(19) United States
(12) Patent Application Publication
(10) Pub. No.: US 2023/0420613 A1
(43) Pub. Date: Dec. 28, 2023

(54) ULTRAVIOLET SEMICONDUCTOR LIGHT-EMITTING ELEMENT

(71) Applicant: STANLEY ELECTRIC CO., LTD., Tokyo (JP)

(72) Inventors: Toru KINOSHITA, Tokyo-to (JP); Akio OGAWA, Tokyo-to (JP); Hiroyuki KANO, Tokyo-to (JP)

(73) Assignee: STANLEY ELECTRIC CO., LTD., Tokyo (JP)

(21) Appl. No.: 18/335,843

(22) Filed: Jun. 15, 2023

(30) Foreign Application Priority Data
Jun. 24, 2022 (JP) 2022-101510

(51) Int. Cl. H01L 33/32; H01L 33/02; H01L 33/16

(52) U.S. Cl. CPC H01L 33/325; H01L 33/025; H01L 33/16

(57) ABSTRACT

An object of the present invention is to provide an ultraviolet semiconductor light-emitting element that allows a user to easily confirm whether or not it is driven to emit the deep ultraviolet light. An ultraviolet semiconductor light-emitting element according to the present invention includes a single crystal AlN substrate, an n-type AlGaN layer, an active layer, and a p-type AlGaN layer. The n-type AlGaN layer is formed on the single crystal AlN substrate. The active layer is formed on the n-type AlGaN layer. The active layer has a light emission peak wavelength of 250 nm or more and 280 nm or less. The p-type AlGaN layer is formed on the active layer. The C concentration in the single crystal AlN substrate is 3×10¹⁷ atoms/cm³ or more.

### BACKGROUND

### 1. Technical Field

The present invention relates to a semiconductor light-emitting element, in particular, an ultraviolet semiconductor light-emitting element that can emit ultraviolet light.

### 2. Description of the Related Art

In recent years, a semiconductor light-emitting element having a light emission peak wavelength in a deep ultraviolet ray region is attracting attention as a light source having an effect of sterilizing air and water.

For example, JP-A-2019-110168 discloses an optical semiconductor element for a deep ultraviolet region in which an AlGaN-based semiconductor layer is formed on an AlN substrate.

### SUMMARY OF THE INVENTION

When using a device using an optical semiconductor element as described above, since deep ultraviolet light emitted from the optical semiconductor element is likely to affect a human body, it is necessary to urge operators or the like of the device to avoid an exposure to the human body during driving of the optical semiconductor element. Thus, when the optical semiconductor element is driven and emits the deep ultraviolet light, it is ideal to be recognizable at a glance.

However, since the deep ultraviolet light is invisible to the naked eye, even when the optical semiconductor element is visually observed, it is difficult to confirm whether or not the optical semiconductor element is driven, that is, whether or not the deep ultraviolet light is emitted.

The present invention has been made in consideration of the above points, and it is an object of the present invention to provide an ultraviolet semiconductor light-emitting element that allows a user to easily confirm whether or not it is driven to emit the deep ultraviolet light.

An ultraviolet semiconductor light-emitting element according to the present invention includes a single crystal AlN substrate, an n-type AlGaN layer, an active layer, and a p-type AlGaN layer. The n-type AlGaN layer is formed on the single crystal AlN substrate. The active layer is formed on the n-type AlGaN layer. The active layer has a light emission peak wavelength of 250 nm or more and 280 nm or less. The p-type AlGaN layer is formed on the active layer. The C concentration in the single crystal AlN substrate is 3×10¹⁷ atoms/cm³ or more.

An ultraviolet semiconductor light-emitting element according to the present invention includes a single crystal AlN substrate, an n-type AlGaN layer, an active layer, and a p-type AlGaN layer. The n-type AlGaN layer is formed on the single crystal AlN substrate. The active layer is formed on the n-type AlGaN layer. The active layer has a light emission peak wavelength of 250 nm or more and 280 nm or less. The p-type AlGaN layer is formed on the active layer. A light emission peak in a wavelength range of 450 nm or more and 800 nm or less is in a range of 590 nm or more and 610 nm or less in a light emission spectrum.

### BRIEF DESCRIPTION OF THE DRAWINGS

FIG. 1 is a top view of a light-emitting device according to Embodiment 1;

FIG. 2 is a cross-sectional view of the light-emitting device in FIG. 1;

FIG. 3 is a diagram illustrating an optical output at a wavelength of 265 nm of the light-emitting device according to Embodiment 1;

FIG. 4 is a diagram illustrating the optical outputs at a wavelength of 600 nm of the light-emitting device according to Embodiment 1;

FIG. 5 is a diagram illustrating light emission spectra for each driving current of the light-emitting device according to Embodiment 1;

FIG. 6 is a diagram illustrating light emission spectra for each driving current of the light-emitting device according to Embodiment 1;

FIG. 7 is a top view of a light-emitting device according to Embodiment 2;

FIG. 8 is a cross-sectional view of the light-emitting device according to Embodiment 2;

FIG. 9 is a top view of a light-emitting device according to Embodiment 3; and

FIG. 10 is a top view of a light-emitting device according to a modification of Embodiment 3.

### DETAILED DESCRIPTION

Preferred embodiments of the present invention will be described below, and these may be modified and combined, as necessary. In the following descriptions and the attached drawings, identical reference numerals are given to substantially identical or equivalent parts to describe them.

### Embodiment 1

A description will be given of a configuration of a light-emitting device 10 according to Embodiment 1 of the present invention with reference to the attached drawings.

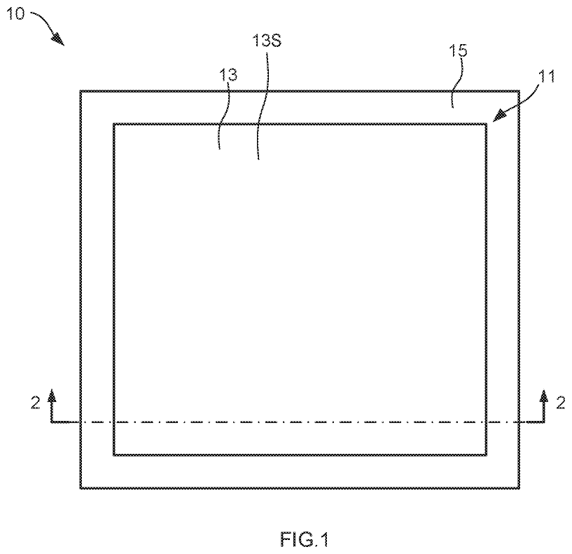

FIG. 1 is a top view of the light-emitting device 10. The light-emitting device 10 is constituted including a sub-mount substrate 15 having a rectangular upper surface shape and an ultraviolet semiconductor light-emitting element 11 including a substrate 13 that is disposed on the sub-mount substrate 15 and has a rectangular upper surface shape. In the light-emitting device 10, a rectangular upper surface 13S of the substrate 13 is a light-emitting surface.

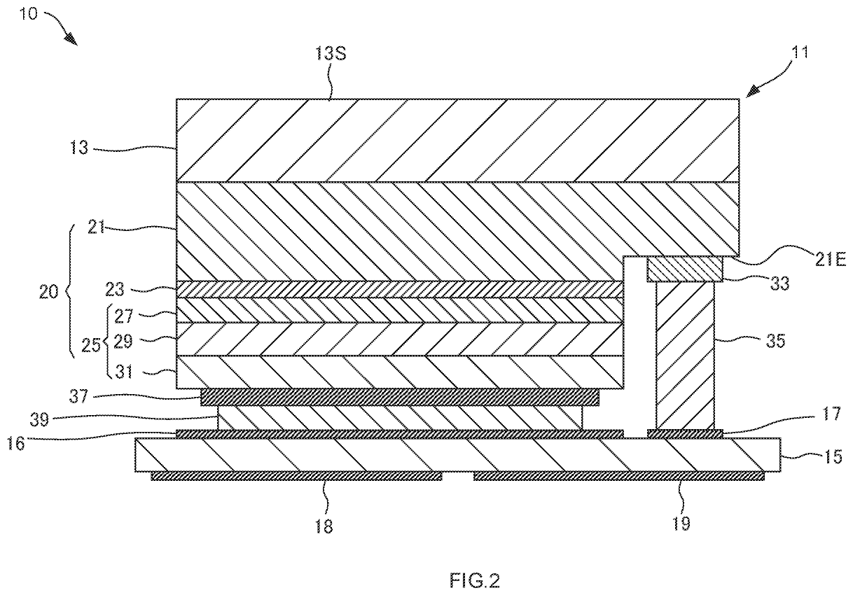

FIG. 2 is a cross-sectional view taken along the line 2-2 of the light-emitting device 10 in FIG. 1. The sub-mount substrate 15 is a plate-shaped substrate having a rectangular upper surface as described above. The sub-mount substrate 15 is an insulating substrate such as an AlN ceramic substrate. The sub-mount substrate 15 may be a substrate made of other materials, for example, a substrate made of a material such as alumina.

A p wiring electrode 16 and an n wiring electrode 17 that are metal electrodes spaced apart with one another are formed on the upper surface of the sub-mount substrate 15. A p rear-surface electrode 18 and an n rear-surface electrode 19 that are metal electrodes spaced apart with one another are formed on a lower surface of the sub-mount substrate 15. The p rear-surface electrode 18 and the n rear-surface electrode 19 are electrically connected to the p wiring electrode 16 and the n wiring electrode 17 via, for example, a through-via, respectively.

The ultraviolet semiconductor light-emitting element 11 is constituted including the substrate 13 and a semiconductor stacked body 20 formed of a plurality of nitride-based semiconductor layers including an active layer formed on the lower surface of the substrate 13. A light emission peak wavelength of the active layer is a light with a wavelength in a deep ultraviolet region, specifically, a light with a wavelength of 250 nm or more and 280 nm or less.

The substrate 13 is a plate-shaped substrate having the rectangular upper surface as described above. The substrate 13 is a single crystal AlN substrate containing C (carbon), Si (silicon), and O (oxygen) as impurities. As described above, the upper surface 13S of the substrate 13 is the light-emitting surface of the light-emitting device 10. The substrate 13 has an optical physical property of absorbing a part of incident ultraviolet light having a wavelength of 250 nm to 280 nm and emitting a visible light in response to the absorption.

The semiconductor stacked body 20 is a stacked structure body including a plurality of semiconductor layers formed to cover the lower surface of the substrate 13.

The semiconductor stacked body 20 includes an n-type cladding layer 21, an active layer 23, and a p-type semiconductor layer 25 that are epitaxially grown in sequence on the substrate 13 by Metal Organic Chemical Vapor Deposition (MOCVD).

The n-type cladding layer 21 is an AlGaN layer that is formed to cover the lower surface of the substrate 13 and is doped with n-type impurities to have conductive property. The n-type cladding layer 21 is doped with, for example, Si as the n-type impurities.

The n-type cladding layer 21 has a mesa shape. Specifically, the n-type cladding layer 21 has one region (the right side portion in the drawing) recessed along an outer edge of a lower surface, and the other region other than the one region is a plateau portion.

An AlN buffer layer that is lattice-matched to the substrate 13 may be disposed between the substrate 13 and the n-type cladding layer 21.

The active layer 23 is formed on the mesa-shaped plateau portion of the lower surface of the n-type cladding layer 21. The active layer 23 has a quantum well structure constituted of a barrier layer and a well layer that are AlGaN layers having mutually different composition ratios. The light emission peak wavelength of the active layer 23 is within a range of 250 nm to 280 nm.

The structure of the active layer 23 is not particularly limited as long as it is constituted to have a light emission peak wavelength of 250 nm to 280 nm. For example, by appropriately setting Al composition and a film thickness of the well layer, and the Al composition and the like of the barrier layer, the light emission peak wavelength can be set to 250 nm to 280 nm. The well layer and the barrier layer may be n-type layers doped with Si.

The number of quantum well layers is not particularly limited, and a Multi Quantum Well (MQW) Structure in which a plurality of well layers are formed may be used, or a Single Quantum Well (SQW) may be used. For example, it is preferred that the number of well layers is appropriately determined within a range of 1 to 5.

The p-type semiconductor layer 25 is constituted by stacking an electron blocking layer 27, a p-type cladding layer 29, and a contact layer 31 on the active layer 23 in this order.

The electron blocking layer 27 is an AlN layer that is formed on the active layer 23 and contains Mg (magnesium) as a p-type dopant. The electron blocking layer 27 functions as an Electron Blocking Layer (EBL) for suppressing the electrons injected into the active layer 23 from overflowing into the p-type cladding layer 29.

The electron blocking layer 27 may be formed not to contain the p-type dopant. The ultraviolet semiconductor light-emitting element 11 may be constituted without the electron blocking layer 27.

The p-type cladding layer 29 is an AlGaN layer that is formed on the electron blocking layer 27 and is doped with Mg as the p-type dopant.

The contact layer 31 is a GaN layer that is formed on the p-type cladding layer 29 and doped with Mg as the p-type dopant. The contact layer 31 is disposed for a purpose of decreasing contact resistance with an electrode disposed on the contact layer 31.

As a p-type dopant material for the electron blocking layer 27, the p-type cladding layer 29, and the contact layer 31, in addition to Mg, Zn (zinc), Be (beryllium), C (carbon), and the like can be used.

An n-electrode 33 is a metal electrode disposed on an exposed surface 21E of n-type cladding layer 21. The n-electrode 33 is electrically coupled to the n-type cladding layer 21. The n-electrode 33 is electrically coupled to the n wiring electrode 17 on the sub-mount substrate 15 via a conductive joining member 35.

A p-electrode 37 is a metal electrode disposed on the contact layer 31. The p-electrode 37 is electrically connected to the contact layer 31. The p-electrode 37 is electrically connected to the p wiring electrode 16 on the sub-mount substrate 15 via a conductive joining member 39.

As described above, the ultraviolet semiconductor light-emitting element 11 is flip-chip mounted on the sub-mount substrate 15. While a case where the ultraviolet semiconductor light-emitting element 11 has a mesa shape has been described, it is not limited to this, and the n-type cladding layer 21 may be electrically connected to the n wiring electrode 17 via a through-bore that is disposed in the semiconductor stacked body 20 and reaches the n-type cladding layer 21.

With the configuration as described above, when current is injected into the light-emitting device 10 via the p rear-surface electrode 18 and the n rear-surface electrode 19, from the active layer 23 of the ultraviolet semiconductor light-emitting element 11, the deep ultraviolet light having the light emission peak wavelength of 250 nm or more and 280 nm or less is emitted. From the upper surface 13S of the substrate 13, visible light generated by absorption of the deep ultraviolet light in the substrate 13 is emitted together with the deep ultraviolet light.

[Preferred Optical Physical Property of Substrate 13]

Subsequently, the optical physical property of the substrate 13 and a configuration of the substrate 13 that provides a favorable optical physical property to the light-emitting device 10 will be described in detail. As described above, the substrate 13 has the optical physical property of absorbing a part of the emitted light from the active layer 23 and emitting a light with a longer wavelength than a wavelength of the emitted light.

Specifically, the substrate 13 absorbs a part of the light having a wavelength of 250 nm or more and 280 nm or less and with a peak at a wavelength of about 265 nm (hereinafter also simply referred to as deep ultraviolet light) emitted from the active layer 23 and emits the light having a wavelength of 590 nm or more and 610 nm or less and with a peak at a wavelength of about 600 nm (hereinafter also simply referred to as red color light) by an absorption and emission process by impurities contained in the substrate 13.

In the light-emitting device 10, during driving, visible light that looks orange color to red color and is visually recognizable is preferably emitted from the light-emitting surface 13S such that a user can easily visually recognize that the ultraviolet semiconductor light-emitting element 11 is emitting light. The colors from orange color to red color, in addition to being the colors that are easily visually recognizable, often have meaning of generally indicating a warning or prohibition, and also can urge a user to call attention to a fact that the ultraviolet semiconductor light-emitting element 11 is emitting the light, and thus, are preferred as a light emission color of the ultraviolet semiconductor light-emitting element 11.

To achieve the emission of the red color light looking orange color to red color, in the light-emitting device 10, an emission spectrum of the light emitted from a light-emitting surface 13S preferably has a peak in a range of 590 nm or more and 610 nm or less in a wavelength range of 450 nm to 800 nm of the visible light. In order to make the emitted red color light visually recognizable, it is preferred that the red color light has a predetermined optical output or more (for example, 0.15 μW or more).

As a light-emitting device, in order to emit the red color light that can be visually recognized as described above while obtaining sufficient light emission intensity of the deep ultraviolet light that achieves the main purpose such as sterilization by the deep ultraviolet light, the substrate 13 needs to absorb the deep ultraviolet light to an extent of being able to obtain the sufficient red color light emission, while suppressing the absorption of the deep ultraviolet light to a minimum. The following describes a mechanism by which the visible light is emitted in the substrate 13 in the light-emitting device 10 and a preferred configuration of the substrate 13 based on the mechanism.

[Mechanism of Emitting Visible Light]

As described above, in the substrate 13, absorption of the ultraviolet light originated from impurities and light emission of the visible light by the absorption occurs. A light absorption mechanism of the ultraviolet light and a light emission mechanism of visible light including the light with a wavelength of about 600 nm due to the impurities in the substrate 13 will be examined.

It is known that single crystal AlN can take various light absorption and light emission patterns depending on the impurity species and impurity concentrations contained in the crystal. Table 1 indicates examples of absorption energy (eV) and light emission energy (eV) of defect structures and substitution structures that cause the light emission by absorbing the light in the vicinity of 250 nm to 280 nm, which is the light emission wavelength of the ultraviolet semiconductor light-emitting element 11 of this embodiment.

TABLE 1

| | Defect Structure and | Absorption | Light Emission |
|---|---|---|---|
| | Substitution Structure | (eV) | (eV) |
| 1 | C_{N} | 4.7 | 3.9/2.8 |
| 2 | C_{N}—Si_{Al} | 5.5 | 4.3 |
| 3 | Adjacent C_{N} and O_{N} | 4.7 | 2.19 |
| 4 | Adjacent C_{N} and V_{N} | 4.7 | 1.9 |

In Table 1, “C_{N}” indicates a point defect in which a nitrogen site of an AlN crystal is substituted by C. In Table 1, “Si_{Al}” indicates an Si substitution of an Al site of the AlN crystal, and “O_{N}” indicates an O substitution of the nitrogen site. “V_{N}” indicates a nitrogen defect resulting from desorption of nitrogen from the nitrogen site of the AlN crystal.

It has been reported that “C_{N}” in which the nitrogen site is substituted with C exhibits absorption of the light of 4.7 eV corresponding to a wavelength of about 265 nm and exhibits the light emission of 3.9 eV (≈320 nm) and 2.8 eV (≈440 nm) (see Applied Physics Letters 104, 202106 (2014)).

“C_{N}—Si_{Al}” as a complex (composite body) of “C_{N}” and “Si_{Al}” exhibits the absorption of the light of 5.5 eV and the light emission of 4.3 eV. This “C_{N}—Si_{Al}” is formed when an Si concentration is larger than a C concentration in the AlN crystal (see Applied Physics Letters 104, 202106 (2014)).

It has been reported that due to a donor-acceptor transition between “O_{N}” as a donor defect and its adjacent “C_{N}” as an acceptor, the absorption of 4.7 eV (≈265 nm) and the light emission of 2.19 eV (≈570 nm) occur (see Semiconductor Science and Technology 35 (2020) 125006).

It has been reported that due to the donor-acceptor transition between “V_{N}” as the donor defect and its adjacent “C_{N}” as the acceptor, the absorption of 4.7 eV (≈265 nm) and the light emission of 1.9 eV (≈650 nm) occur (see Semiconductor Science and Technology 35 (2020) 125006).

From the above, it is presumed that “C_{N}” in the substrate 13 is the main factor in the absorption at a wavelength of 265 nm (4.7 eV) in the present invention. It is presumed that red color light emission at 600 nm (=2.07 eV) in the present invention is due to the donor-acceptor transition between the donor defect, such as “O_{N}” and “V_{N},” and “C_{N}” as the acceptor.

[Preferred Configuration of Substrate 13]

Based on the above-described mechanism, a preferred configuration of the substrate 13 will be described below.

[Absorption Coefficient]

The substrate 13 preferably has the absorption coefficient of 15 cm⁻¹ or more relative to the deep ultraviolet light with the light emission peak wavelength of the active layer 23. As described above, it is believed that C_{N} is the main factor in the absorption of the deep ultraviolet light.

When the absorption coefficient is 15 cm⁻¹ or less, for example, even when the thickness of the substrate 13 is increased, it is difficult to obtain the red color light emission sufficient to an extent of being visually recognizable. It is believed that this is because the absorption and emission process by the donor-acceptor transition between adjacent “C_{N}” and “O_{N}” or between adjacent “C_{N}” and “V_{N}” as described above is unlikely to occur due to the low C_{N} concentration in the substrate 13.

For example, in a conventional AlN substrate, from a viewpoint of suppressing a total amount of the ultraviolet light that can be extracted outside from decreasing, and thus, suppressing light emission efficiency from decreasing, due to the absorption of the ultraviolet light emitted from the active layer by the substrate, for example, the absorption coefficient of the AlN substrate is preferably 20 cm⁻¹ or less, more preferably 10 cm⁻¹ or less, and efforts have been made to lower the absorption coefficient.

In contrast, in this embodiment, in order to ensure a sufficient absorption amount to generate the red color light by the absorption of the ultraviolet light, the absorption coefficient relative to the light with the light emission peak wavelength of the active layer 23 is set to 15 cm⁻¹ or more.

When the absorption coefficient is 15 cm⁻¹ or more, by appropriately setting the thickness of the substrate 13, the sufficient red color light emission is obtained to the extent of being visually recognizable. In this embodiment, the absorption coefficient is controlled to 15 cm⁻¹ or more by setting the impurity concentration contained in the substrate 13 to a predetermined value or more.

[Internal Transmittance]

When the absorption coefficient is 15 cm⁻¹ or more, the absorption amount of the deep ultraviolet light by the substrate 13 varies depending on the thickness of the substrate 13 in addition to the absorption coefficient of the substrate 13. A balance between the absorption amount of the deep ultraviolet light by the substrate 13 and a total amount of the deep ultraviolet light that can be extracted outside from the light-emitting surface 13S can be estimated by the internal transmittance of the substrate 13. When the absorption coefficient relative to the light with the light emission peak wavelength of the substrate 13 is a, and the thickness of the substrate 13 is x, the internal transmittance τ is expressed by the following Formula.

τ=exp(−ax) Formula 1

From the viewpoint of extracting the deep ultraviolet light with the sufficient light emission intensity and the red color light with the sufficient light emission intensity to the extent of being easily visually recognizable from the light-emitting surface 13S, the above-described internal transmittance is preferably 30% or more and 70% or less.

When the internal transmittance is less than 30%, increasing the absorption amount of the light with a wavelength of 265 nm allows obtaining a high output light with a wavelength of about 600 nm, but on the other hand, a reduction amount in the light emission intensity at a wavelength of 265 nm increases, it is not preferred from the viewpoint of the light emission efficiency of the deep ultraviolet light and the red color light.

When the internal transmittance exceeds 70%, since the absorption amount of the light with a wavelength of 265 nm by the substrate 13 is small, the light emission intensity at a wavelength of 265 nm is large. However, in this case, sufficient light emission intensity of the light with a wavelength of about 600 nm is not obtained since the absorption amount of the light with a wavelength of 265 nm is small, it is not preferred from the viewpoint of extracting the red color light.

Considering the above-described points, the internal transmittance for the light with the light emission peak wavelength of the active layer 23 by the substrate 13 is preferably 30% or more and 70% or less, more preferably 40% or more and 60% or less.

[Relationship between Absorption Coefficient of Single Crystal AlN Substrate and Thickness]

Furthermore, from the viewpoint on manufacturing of the substrate 13, the absorption coefficient relative to the light of 265 nm of the substrate 13 is preferably 50 cm⁻¹ or less. When the absorption coefficient exceeds 50 cm⁻¹, variation in the absorption amount of the light of 265 nm increases due to change in the thickness of the substrate. In this case, variations in the thickness of the substrate 13 during manufacturing result in changes in the properties of the element. Accordingly, in order to suppress variations in the thickness of the substrate 13, it is necessary to reduce a tolerance of the thickness of the substrate 13. Thus, considering that when the absorption coefficient exceeds 50 cm 1, requirements for processing accuracy in manufacturing become stricter, the absorption coefficient of the substrate 13 is preferably set to 50 cm⁻¹ or less.

From a similar reason, the thickness of the substrate 13 is preferably set to 150 m or more. When the thickness of the substrate 13 is less than 150 m, in order to obtain sufficient absorption amount of the light with a wavelength of 265 nm, it is necessary to increase the absorption coefficient of the substrate 13, and the tolerance of the thickness of the substrate 13 is reduced as described above.

In a conventional single crystal AlN substrate, while the thickness that allows obtaining sufficient strength as a growth substrate for the light emitting element is 90 m to 100 m, in this embodiment, due to relationship with the absorption coefficient of a wavelength of 265 nm, the thickness is preferably 150 m or more.

From the viewpoint of manufacturing, such as the fact that the manufacturing cost increases when the thickness of the substrate 13 exceeds 500 m, the thickness of the substrate 13 is preferably 500 m or less.

From the above, considering the viewpoint of manufacturing, it is preferred that the substrate 13 has an absorption coefficient of 15 cm⁻¹ or more and 50 cm⁻¹ or less and a thickness of 150 m or more and 500 m or less.

[Impurity Concentration Control in Single Crystal AlN Substrate]

The impurity concentration control in the substrate 13 in the present invention will be described. As described above, the substrate 13 contains C, Si, and O as impurities. These impurities are impurities that are introduced when the substrate 13 is grown and are intentionally introduced by controlling the concentration. The C concentration, the Si concentration, and an O concentration in the substrate 13 can be measured by a Secondary Ion Mass Spectrometry (SIMS).

In the light-emitting device 10 of the present invention, as described above, the absorption and emission process mainly caused by C among the impurities in the substrate 13 is used to absorb the light with a wavelength of 265 nm from the active layer 23 and generate the red color light with a wavelength of about 600 nm. As described above, it is presumed that the absorption of a wavelength of 265 nm (4.7 eV) is mainly caused by “C_{N}” where the nitrogen site of the AlN crystal in the substrate 13 is substituted with C. Accordingly, in order to generate the red color light in the present invention, controlling the C_{N} concentration in the substrate 13 is important.

It is known that C incorporated in the AlN crystal preferentially substitutes the nitrogen site (see Applied Physics Letters 100, 191914 (2012)). Accordingly, basically, the C concentration in the AlN crystal can be regarded as the C_{N} concentration ((the C_{N}concentration≈the C concentration).

However, as indicated in Table 1, when the Si concentration in the substrate 13 is higher than the C concentration, since the C_{N} concentration is reduced by formation of the C_{N}—Si_{Al}, which is the complex of C_{N} and Si_{Al}, the C concentration cannot be regarded as the C_{N} concentration. In the following, a case where the Si concentration is equal to or less than the C concentration and a case where the Si concentration is higher than the C concentration will be described, respectively.

First, when the Si concentration in the substrate 13 is equal to or less than the C concentration (the Si concentration≤the C concentration), it is considered that little or negligible C_{N}—Si_{Al} is formed. Accordingly, the C concentration can be regarded as the C_{N}concentration, and the C_{N} concentration can be controlled by controlling the C concentration.

It is known that the absorption coefficient α of the AlN crystal relative to the light of 265 nm (4.7 eV) is determined by the C_{N} concentration in the AlN crystal (see Applied Physics Letters 100, 191914 (2012)). Accordingly, the C_{N} concentration for obtaining the red color light together with the deep ultraviolet light by generating the appropriate absorption and light emission in the substrate 13 can be estimated based on the absorption coefficient α.

The relationship between the C concentration in the single crystal AlN substrate and the absorption coefficient α of the single crystal AlN substrate relative to the light of 4.7 eV (≈265 nm) is disclosed in Applied Physics Letters 100, 191914 (2012) and Applied Physics Express 5 (2012) 125501.

As described above, since it is difficult to obtain the red color light regardless of the thickness of the substrate 13 when the absorption coefficient α is less than 15 cm⁻¹, in the present invention, the absorption coefficient α of the substrate 13 needs to be 15 cm-1 or more. According to the relationship between the above-described C concentration and the absorption coefficient α, the C concentration corresponding to an absorption coefficient of 15 cm⁻¹ of the light with a wavelength of 265 nm can be estimated as 3×10¹⁷ atoms/cm³.

In the light-emitting device 10 of the present invention, by controlling the C concentration in the substrate 13 to 3×10¹⁷ atoms/cm³ or more, the absorption coefficient α relative to the light with a wavelength of 265 nm by the substrate 13 is controlled to 15 cm⁻¹ or more.

According to the relationship between the above-described C concentration and the absorption coefficient α, the C concentration corresponding to 50 cm⁻¹ as an upper limit value of the absorption coefficient α in which a thickness tolerance of the substrate is taken into consideration can be estimated as 3×10¹⁸ atoms/cm³. Accordingly, when the C concentration can be regarded as the C_{N} concentration, a preferred C concentration range for setting the absorption coefficient α to be 15 cm⁻¹ or more and 50 cm⁻¹ or less is 3×10¹⁷ atoms/cm³ or more and 3×10¹⁸ atoms/cm³ or less.

Subsequently, a case where the Si concentration is higher than the C concentration (the Si concentration>the C concentration) will be described. As described above, when the Si concentration is higher than the C concentration, C_{N}—Si_{Al}, which is the complex of C_{N} and Si_{Al}, is formed. C_{N}—Si_{Al} exhibits an absorption of 5.5 eV and does not absorb the light of 265 nm (4.7 eV). C_{N}—Si_{Al} exhibits a light emission of 4.3 eV and does not emit the red color light with a wavelength of 600 nm (=2.07 eV).

In this case, it cannot be regarded as C_{N} concentration≈C concentration, the C_{N}concentration is the concentration obtained by subtracting C_{N}—Si_{Al} concentration from the C concentration, that is, “C_{N} concentration≈C concentration−(C_{N}—Si_{Al} concentration). Accordingly, even when the C concentration is the same, the absorption coefficient α relative to the light of 265 nm is smaller compared to a case where the Si concentration is equal to or less than the C concentration. Therefore, the C concentration in the substrate 13 needs to be set higher by the amount used for forming C_{N}—Si_{Al}.

Actually, using a sample with the Si concentration higher than the C concentration, an absorption coefficient α of 20 cm⁻¹, a C concentration of 6×10¹⁸ atoms/cm³, a Si concentration of 2.5×10¹8 atoms/cm³, the C_{N}—Si_{Al} concentration is calculated to be approximately 5×10¹⁸ atoms/cm³. A relational expression of α=5.672E⁻¹²X^{0.6978} (X is the C_{N} concentration) is used for calculation of the C_{N} concentration.

From the above-described calculation result, when the Si concentration is higher than the C concentration, the C concentration for setting the absorption coefficient α to be 15 cm⁻¹ or more and 50 cm⁻¹ or less can be estimated to be 5.3×10¹⁸ atoms/cm³ or more and 8.0×10¹⁸ atoms/cm³ or less.

In addition to the case where the Si concentration is lower than the C concentration, considering the case where the Si concentration is higher than the C concentration, in the present invention, a preferred C concentration range for setting the absorption coefficient α of the substrate 13 to be 15 cm⁻¹ or more and 50 cm-1 or less relative to the light with a wavelength of 265 nm can be estimated to be 3×10¹⁷ atoms/cm³ or more and 8×10¹⁸ atoms/cm³ or less.

Furthermore, the inventors of the present invention have found that when the sum of the Si concentration and the O concentration in the substrate 13 is controlled to be higher than the C concentration in the substrate 13 (Si concentration+O concentration>C concentration), the light emission intensity of the deep ultraviolet light as the main object can be sufficiently obtained, and the visible red color light can be emitted.

When the sum of the Si concentration and the O concentration is set to be higher than the C concentration in the substrate 13, it is considered that this is because the absorption of the light with a wavelength of 265 nm due to C_{N} is suppressed by the formed C_{N}—Si_{Al}, and excessive decrease in transmittance is suppressed.

These impurities may be impurities that naturally enter during manufacturing of the substrate 13. In that case, it is only necessary to select a substrate containing impurities with desired concentration as the substrate 13.

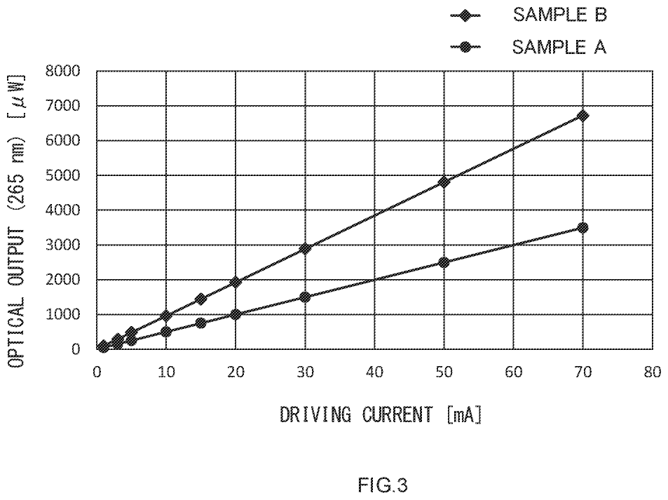

With reference to FIGS. 3 to 6, light emission properties of a sample A and a sample B of this embodiment will be compared and described.

In the light-emitting device 10 of this embodiment, the sample A is one in which the absorption coefficient of the substrate 13 is set to 20 cm⁻¹, and the thickness of the substrate 13 is set to 400 m. The ample B differs from the sample A only in that the substrate 13 has a thickness of 100 m, and is configured similarly to the sample A in other respects.

Accordingly, in the sample A and the sample B, the absorption coefficients of the substrates 13 are both 20 cm⁻¹. In the sample A and the sample B, the impurity concentrations in the substrates 13 are 6×10¹⁸ atoms/cm³ for the C concentration, 2.5×10¹⁸ atoms/cm³ for the Si concentration, and 4.5×10¹8 atoms/cm³ for the O concentration. Accordingly, the sample A and the sample B are controlled such that the sums of the Si concentrations and the O concentrations in the substrates 13 are larger than the C concentrations ((Si+O)/C=1.17). By disposing an optical detector on the light-emitting surface 13S of each of the sample A and the sample B, the optical output and the light emission spectrum when the driving current is varied from 5 mA to 70 mA are measured.

FIG. 3 is a diagram illustrating the optical output at a wavelength of 265 nm relative to the driving current for the sample A and the sample B. As illustrated in FIG. 3, in both the sample A and the sample B, the optical outputs at a wavelength of 265 nm increase as the driving current increases. The optical output value of the sample A is smaller than that of the sample B at the same driving current.

This is because the sample A has a thickness of the substrate 13 larger than that of the sample B and has the lower internal transmittance, and thus, the absorption amount of the light with a wavelength of 265 nm is larger. Specifically, for the light with a wavelength of 265 nm, the internal transmittance of the sample A is approximately 45%, and the internal transmittance of the sample B is approximately 82%.

When the light-emitting device 10 is actually used, it is driven with a driving current of about 400 mA, which is larger than that in this experiment. In that case, even when the light-emitting device of the sample A is used, the optical output of, for example, 30 mW or more, which is sufficient for applications such as sterilization, can be obtained.

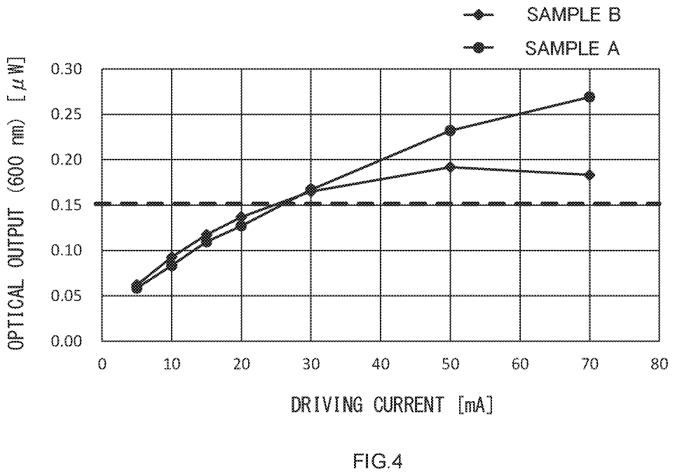

FIG. 4 is a diagram illustrating the optical outputs at a wavelength of 600 nm relative to the driving current for the sample A and the sample B. In FIG. 4, a line of 0.15 W as a level of the visible optical output is indicated by a dashed line.

As illustrated in FIG. 4, in both the sample A and the sample B, the optical outputs at a wavelength of 600 nm increase as the driving current increases up to a driving current of 30 mA. Both the sample A and the sample B exceed 0.15 μW as a level of the visible optical output at a driving current of 30 mA or more.

When the driving current exceeds 30 mA, in the sample A, the optical output at a wavelength of 600 nm increases as the driving current increases. In contrast, in the sample B, when the driving current exceeds 30 mA, even when the driving current increases, a range of increase of the optical output at a wavelength of 600 nm is decreased, and when the driving current exceeds 50 mA, the optical output at a wavelength of 600 nm does not increase. In the sample B, it is considered that when the driving current exceeds 30 mA, absorption sites for the light with a wavelength of 265 nm become shortage, and the optical output at a wavelength of 600 nm tends to saturate.

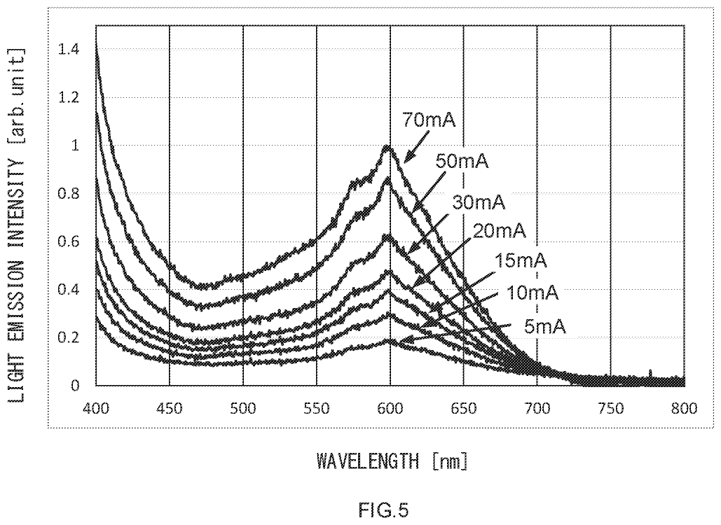

FIG. 5 is a diagram illustrating a light emission spectrum from a wavelength of 400 nm to a wavelength of 800 nm for each driving current when the driving current is varied from 5 mA to 70 mA in the sample A. As illustrated in FIG. 5, in the light emission spectrum of the sample A, the light emission intensity at a wavelength of approximately 600 nm is maximum at any driving current. In other words, in the light emission spectrum of the sample A, the light emission peak in a wavelength range of 450 nm or more and 800 nm or less is within a range of 590 nm or more and 610 nm or less.

Thus, when the light emission intensity at a wavelength of approximately 600 nm in the visible light region is maximum, the light from orange color to red color can be visually recognized.

The position of the light emission peak at the approximately 600 nm does not change from the position at an approximately 600 nm even when the driving current varies. Accordingly, in the sample A, it is considered that even when the driving current is increased up to an extent of 400 mA, which is a practical driving current as described above, tendency for the light emission peak in a wavelength range of 450 nm or more and 800 nm or less to be within a range of 590 nm or more and 610 nm or less is maintained.

Accordingly, when the sample A is driven by a driving current of around 400 mA, the visible light from orange color to red color together with the deep ultraviolet light is emitted from the light-emitting surface 13S of the sample A, and the visible light allows the state of being driven to be easily recognized at a glance.

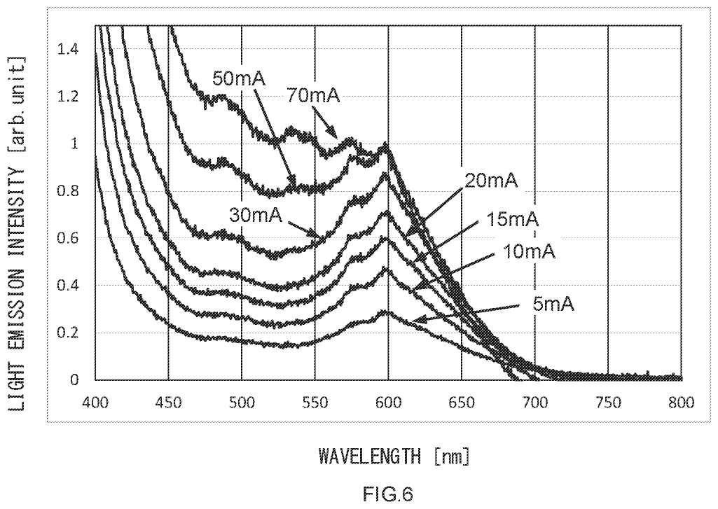

FIG. 6 is a diagram illustrating the light emission spectrum from a wavelength of 400 nm to a wavelength of 800 nm for each driving current when the driving current is varied from 5 mA to 70 mA in the sample B. As illustrated in FIG. 6, in the light emission spectrum of the sample B, the light emission intensity at a wavelength of approximately 600 nm is maximum up to a driving current of 30 mA. As illustrated in FIG. 4, the sample B exceeds 0.15 μW as a level of visible optical output in a driving current of 30 mA or more. Accordingly, it can be said that at least under a condition of a driving current of 30 mA, the red color light can be recognized by driving the sample B.

However, in FIG. 6, in the spectrums at 50 mA and 70 mA, even when the driving current increases from 50 mA to 70 mA, the light emission intensity at a wavelength of 600 nm does not increase, and the light emission intensity of the light with a wavelength of 450 nm or more and less than 600 nm, that is, the light emission intensity at a wavelength shorter than 600 nm increases in the light in the visible light region. It is considered that this is because of the light emission from the contact layer 31, which is the p-type GaN layer.

In this case, the light emission color that is visually recognizable tends to be from bluish white color to white color (hereinafter simply also referred to as bluish white light), not from orange color to red color, by color mixture of the light with a wavelength of approximately 600 nm and the light with a wavelength of 450 nm or more and less than 600 nm.

For example, in the sample B, it is considered that when the driving current is increased up to the extent of 400 mA, which is a practical driving current, the light emission intensity at a wavelength of approximately 600 nm does not increase any more, and the tendency that the light emission intensity at a wavelength of 450 nm or more and less than 600 nm is high is maintained.

Accordingly, when the sample B is driven with a driving current of around 400 mA, the bluish white light can be emitted together with the deep ultraviolet light from the light-emitting surface 13S of the sample B. While the driving of the sample B can be recognized by the visible light being emitted from the sample B, the bluish white light tends to be more difficult to recognize compared with the red color light, and thus, it can be said that the sample A, which emits the red color light, is more preferred.

In this embodiment, the light emission spectrum that exhibits the bluish white light due to the contact layer 31, which is the p-type GaN layer as described above, is observed in the sample B. The light emission intensity of the bluish white light varies depending on quality and a film thickness of the pGaN contact layer and is sometimes such that it is difficult to visually recognize it.

As it was remarkable in the sample A, in the present invention, the light emission spectrum of the light-emitting device 10 has a peak at approximately 600 nm in the region of 450 nm to 800 nm. This wavelength of 600 nm is due to the absorption and emission process caused mainly by C_{N} as described above, and basically does not change. However, this peak wavelength is sometimes shortened by an increase in an excitation density (a current density) or is sometimes lengthened when the temperature increases. Even considering these things, the peak wavelength in the region of 450 nm to 800 nm due to the absorption and emission process by the impurities in the substrate 13 is considered to be within 600 nm ±5 nm, and even when the peak wavelength is roughly estimated, it can be said that the peak wavelength is within 600 nm ±10 nm.

[Manufacturing Method of Single Crystal AlN Substrate]

The substrate 13 can be manufactured by, for example, a Physical Vapor Transport (PVT) method. In the PVT method, an AlN raw material such as polycrystalline AlN is heated and sublimated to grow a crystal on a seed substrate disposed to be opposed to a crucible containing the raw material.

For example, by using an AlN raw material containing an initial low impurity amount, the impurity concentration in the growing single crystal AlN substrate can be reduced.

Since the impurity amount in a gas phase varies by controlling temperature conditions such as the temperature of the raw material during crystal growth and pressure conditions inside a reactor, the impurity amount incorporated into the AlN single crystal can be controlled in accordance therewith. For example, when the temperatures are lowered, the impurity concentration tends to decrease.

By adding impurity raw materials such as Si pieces and carbon pieces together with the AlN raw material and controlling the above-described temperature conditions and pressure conditions in addition to its addition amount, the impurity concentration in the single crystal AlN substrate can be increased or decreased.

The substrate 13 can be grown not only by the PVT method, but also by, for example, a Hydride Vapor Phase Epitaxy (HVPE) method, a Molecular Beam Epitaxy (MBE) Method, or an MOCVD method, or by a combination of these methods.

It is preferred to grow the substrate 13 by the PVT method considering a long growth time of the MBE method or the MOCVD method and a high cost of the HVPE method.

As described above in detail, the light-emitting device 10 of this embodiment is constituted by mounting the ultraviolet semiconductor light-emitting element 11 on the sub-mount substrate. The ultraviolet semiconductor light-emitting element 11 has the single crystal AlN substrate, the n-type cladding layer, the active layer having the light emission peak wavelength of 250 nm or more and 280 nm or less, and the p-type cladding layer, and the C concentration in the single crystal AlN substrate is 3×10¹¹ atoms/cm³ or more.

In other words, in the light emission spectrum of the ultraviolet semiconductor light-emitting element 11, the light emission peak in a wavelength range of 450 nm or more and 800 nm or less is in the range of 590 nm or more and 610 nm or less.

With the configuration as described above, the single crystal AlN substrate absorbs a part of the deep ultraviolet light, which is the light with the light emission peak wavelength of the active layer, and emits the light in a wavelength range of 590 nm or more and 610 nm or less in response to the absorption of the deep ultraviolet light. In other words, the single crystal AlN substrate emits the light in a wavelength range of 590 nm or more and 610 nm or less due to the absorption of the deep ultraviolet light. The light in a wavelength range of 590 nm or more and 610 nm or less together with the deep ultraviolet light is emitted from the light-emitting surface of the light-emitting device 10. The light in a wavelength range of 590 nm or more and 610 nm or less can be easily visually recognized as the light from orange color to red color. With such red color emission light that is easily visually recognized and generally has a meaning of warning or inhibition, a user of the light-emitting device 10 can recognize at a glance that the semiconductor light-emitting element 11 is being driven, and safety for the operator can be improved.

Therefore, with this embodiment, it is possible to provide the ultraviolet semiconductor light-emitting element that a user can easily confirm whether or not the ultraviolet semiconductor light-emitting element is driven to emit the deep ultraviolet light.

### Embodiment 2

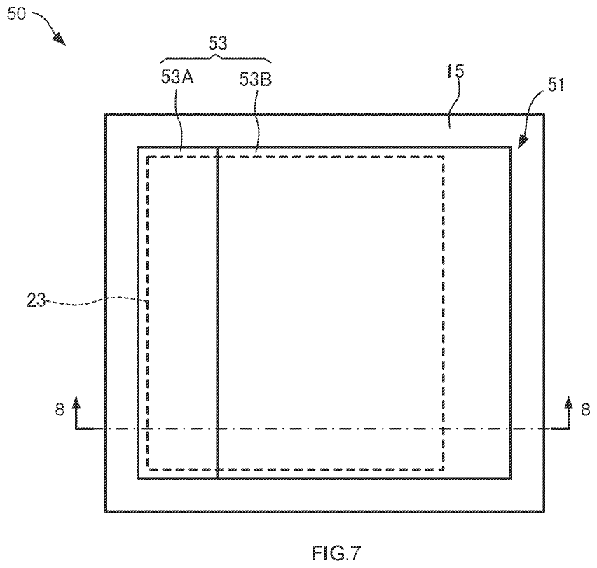

FIG. 7 is a top view of a light-emitting device 50 according to Embodiment 2. As illustrated in FIG. 7, the light-emitting device 50 is constituted including an ultraviolet semiconductor light-emitting element 51. The ultraviolet semiconductor light-emitting element 51 differs from the configuration of Embodiment 1 in that it has a substrate 53 as the single crystal AlN substrate, and is constituted similarly to the ultraviolet semiconductor light-emitting element 11 of Embodiment 1 in other respects.

The substrate 53 has two region of a region 53A and a region 53B in the top view. The substrate 53 has the region 53A having a thickness larger than that of the region 53B. The substrate 53 is constituted similarly to the substrate 13 of Embodiment 1 in other respects.

In FIG. 7, a region in which the active layer 23 is formed on the lower surface side of the substrate 53 is indicated by a dashed line. As illustrated in FIG. 7, the region 53A having a larger thickness of the substrate 53 overlaps with the region where the active layer 23 is formed.

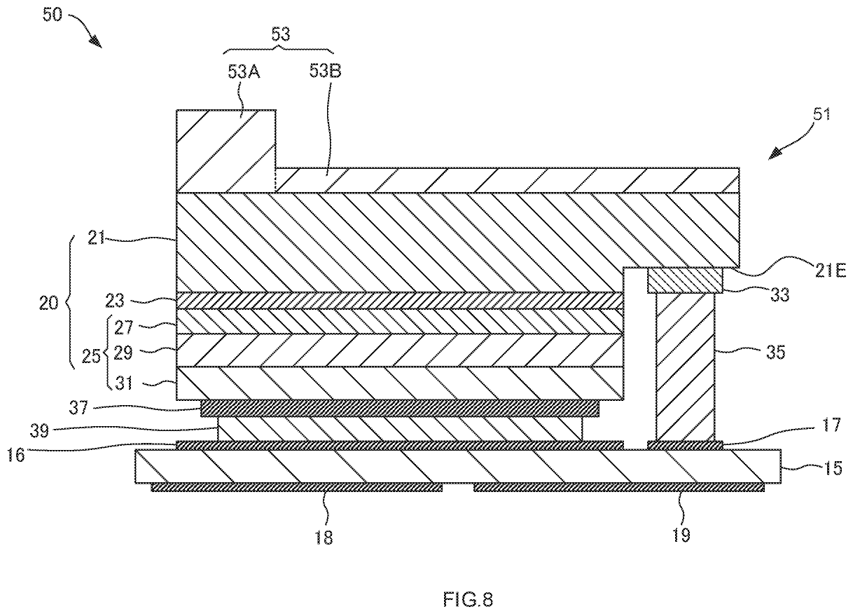

FIG. 8 is a cross-sectional view of the light-emitting device 50 taken along the line 8-8 in FIG. 7. As illustrated in FIG. 8, the substrate 53 has the region 53A having a thickness larger than that of the region 53B.

Specifically, for example, the absorption coefficient of the substrate 53 is 20 cm⁻¹ in any region. The region 53A of the substrate 53 has a thickness of 400 m similarly to the sample A of Embodiment 1 and has the internal transmittance of approximately 45% relative to the light with a wavelength of 265 nm. The region 53B of the substrate 53 has a thickness of 100 m similarly to the sample B of Embodiment 1 and has the internal transmittance of approximately 82% relative to the light with a wavelength of 265 nm.

In other words, the substrate 53 has a region in which the internal transmittance relative to the light with the light emission peak wavelength of the active layer 23 is 30% or more and 70% or less in a plan view. By driving the light-emitting device 50, the red color light is extracted from the region 53A of the substrate 53. From the region 53B, the high output of the deep ultraviolet light is obtained, and no red color light is emitted. For example, similarly to the case of the sample B of Embodiment 1, the visible light of bluish white color to white color can be emitted from the region 53B.

Thus, in this embodiment, the absorption coefficient of the substrate 53 relative to the light of 265 nm is set to 15 cm¹ or more, and the thickness is varied depending on the region. Thus, in the region where the thickness of the substrate 53 is small and the internal transmittance is high, absorption of the light with a wavelength of 265 nm by the substrate 53 is suppressed to ensure a high optical output of the deep ultraviolet light, and at the same time, in the region where the thickness is large and the internal transmittance is low, the red color light with a wavelength of approximately 600 nm that can be easily visually recognized can be emitted.

In Embodiment 2, it is only necessary that the thickness of a part of the region of the substrate 53 is made larger, and it is arbitrary as to which region has a larger thickness. For example, as described above, by forming the region 53A having a larger thickness in the edge region of the substrate 53 in the top view, it is possible to avoid interference against the emission of the deep ultraviolet light by the region 53A.

As illustrated in FIGS. 7 and 8, it is preferred to dispose the region 53A in the region that overlaps with the region where the active layer 23 is formed in the top view. Thus, it is possible to cause the emitted light from the active layer 23 to enter the region 53A and the red color light to be reliably emitted.

The substrate 53 of this embodiment can be formed by, for example, after forming the semiconductor stacked body 20, protecting the semiconductor stacked body 20 with a resist or the like and then forming the region 53B by a method such as wet etching of the single crystal AlN substrate.

In this embodiment, instead of varying the thickness of the substrate in a part of the region of the substrate 53, the impurity concentration of a part of the region of the substrate 53 may be varied, and thus, the red color light may be emitted from the part of the region.

### Embodiment 3

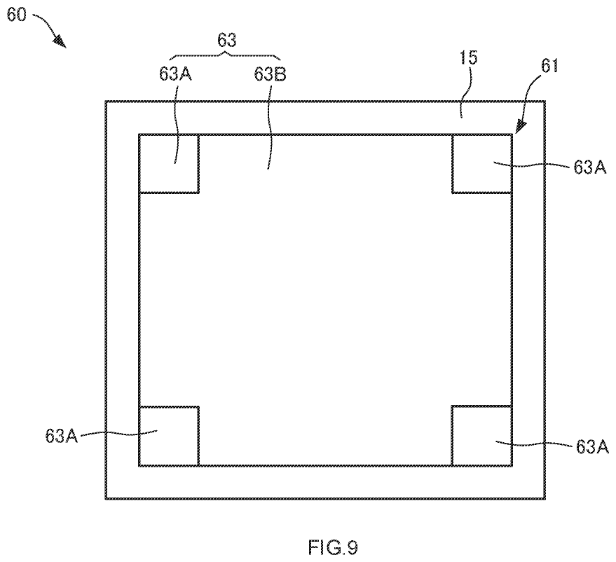

FIG. 9 is a top view of a light-emitting device 60 according to Embodiment 3. As illustrated in FIG. 9, the light-emitting device 60 is constituted including an ultraviolet semiconductor light-emitting element 61. The ultraviolet semiconductor light-emitting element 61 differs from the configuration of Embodiment 1 in that it has a substrate 63 as the single crystal AlN substrate, and is constituted similarly to the ultraviolet semiconductor light-emitting element 11 of Embodiment 1 in other respects.

The substrate 63 has two kinds of regions of regions 63A and a region 63B in the top view. As illustrated in FIG. 9, the substrate 63 has a rectangular upper surface shape. The regions 63A are rectangular regions disposed at four corners of the substrate 63. The region 63B is the remaining region where the regions 63A are excluded from the substrate 63.

The substrate 63 has the regions 63A having a thickness larger than that of the region 63B. The substrate 63 is constituted similarly to the substrate 13 of Embodiment 1 in other respects.

Specifically, for example, the absorption coefficient of the substrate 63 is 20 cm⁻¹ in any region. The region 63A of the substrate 63 has a thickness of 400 m similarly to the sample A of Embodiment 1 and has the internal transmittance of approximately 45% relative to the light with a wavelength of 265 nm. The region 63B of the substrate 63 has a thickness of 100 m similarly to the sample B of Embodiment 1 and has an internal transmittance of approximately 82% relative to the light with a wavelength of 265 nm.

In other words, the substrate 63 has a region in which the internal transmittance relative to the light with the light emission peak wavelength of the active layer 23 is 30% or more and 70% or less in the plan view. By driving the light-emitting device 60, the red color light having a peak at approximately 600 nm in the wavelength range of 450 nm to 800 nm is extracted from the regions 63A of the substrate 63. In the region 63B, the absorption amount of the light of 265 nm is small, the high output of the deep ultraviolet light is obtained, and red color light is hardly emitted. For example, similarly to the case of the sample B of Embodiment 1, the visible light of bluish white color to white color can be emitted from the region 63B.

In this embodiment, since the regions 63A having the large thicknesses are disposed at the four corners of the substrate 63, it can be confirmed whether or not the red color light is emitted from the four regions 63A, or whether or not the red color light is emitted from the four regions 63A with a similar extent of intensity. Thus, it is possible to indirectly confirm whether or not the deep ultraviolet light is uniformly emitted.

The upper surface shapes of the regions 63A can be formed in any shape, in addition to the rectangular shapes illustrated in FIG. 9, for example, shapes such as fan shapes centered on the four corners of the substrate 63 may be employed.

[Modification]

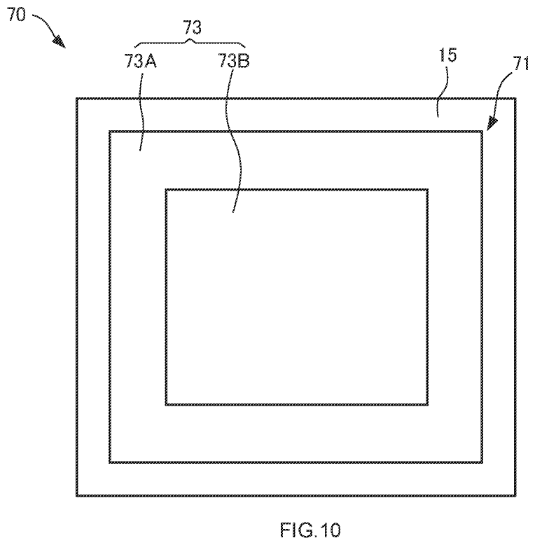

FIG. 10 is a top view of a light-emitting device 70 according to the modification of Embodiment 3. As illustrated in FIG. 10, the light-emitting device 70 is constituted including an ultraviolet semiconductor light-emitting element 71. The ultraviolet semiconductor light-emitting element 71 differs from the configuration of Embodiment 3 in that it has a substrate 73 as the single crystal AlN substrate, and is constituted similarly to the ultraviolet semiconductor light-emitting element 61 of Embodiment 3 in other respects.

The substrate 73 has two kinds of regions of a region 73A and a region 73B in the top view. As illustrated in FIG. 10, the substrate 73 has a rectangular upper surface shape. The region 73A is an annular region disposed along an outer edge of the substrate 73. The region 73B is the remaining region where the region 73A is excluded from the substrate 73.

The substrate 73 has the region 73A having a thickness larger than the region 73B. The substrate 73 is constituted similarly to the substrate 63 of Embodiment 3 in other respects. In this embodiment, since the region 73A having a larger thickness is disposed along the outer edge of the substrate 73, it is possible to confirm whether or not the red color light is uniformly emitted from the region 73A. Thus, it is possible to more reliably confirm whether or not the deep ultraviolet light is uniformly emitted.

For example, in the top view, the region 73A having the larger thickness may be disposed in a shape along two lines that intersect with one another. For example, the region 73A having the larger thickness may be disposed on a diagonal line of the substrate 73. Thus, it is possible to strengthen the implication of warning or attention calling by the red color light emission.

The configurations in the above-described embodiments and the manufacturing methods are merely examples and can be changed appropriately depending on the application and the like.

For example, while in the above-described embodiments the examples in which the ultraviolet semiconductor light-emitting elements are flip-chip mounted are described, it is not limited to this. The surface opposed to the single crystal AlN substrate may be mounted as a light-emitting surface. Even in that case, the light that has undergone the absorption and emission process by the single crystal AlN substrate is emitted from the light-emitting surface.

It is understood that the foregoing description and accompanying drawings set forth the preferred embodiments of the present invention at the present time. Various modifications, additions and alternative designs will, of course, become apparent to those skilled in the art in light of the foregoing teachings without departing from the spirit and scope of the disclosed invention. Thus, it should be appreciated that the present invention is not limited to the disclosed Examples but may be practiced within the full scope of the appended claims. This application is based upon and claims the benefit of priority from the prior Japanese Patent Application No. 2022-101510 filed on Jun. 24, 2022, the entire contents of which are incorporated herein by reference.

What is claimed is:

1. An ultraviolet semiconductor light-emitting element comprising:
a single crystal AlN substrate;
an n-type AlGaN layer formed on the single crystal AlN substrate;
an active layer formed on the n-type AlGaN layer, the active layer having a light emission peak wavelength of 250 nm or more and 280 nm or less; and
a p-type AlGaN layer formed on the active layer, wherein
a C concentration in the single crystal AlN substrate is 3×10¹⁷ atoms/cm³ or more.

2. The ultraviolet semiconductor light-emitting element according to claim 1, wherein
the single crystal AlN substrate has an absorption coefficient of 15 cm¹ or more relative to a light with the light emission peak wavelength of the active layer.

3. The ultraviolet semiconductor light-emitting element according to claim 1, wherein
a sum of an Si concentration and an O concentration in the single crystal AlN substrate is higher than the C concentration.

4. The ultraviolet semiconductor light-emitting element according to claim 1, wherein
the single crystal AlN substrate has a region in a plan view in which an internal transmittance τ is 30% or more and 70% or less, the internal transmittance τ is expressed by a following Formula 1 when the absorption coefficient relative to the light emission peak wavelength of the active layer is α, and a thickness of the single crystal AlN substrate is x.
τ=exp(−ax) Formula 1

5. The ultraviolet semiconductor light-emitting element according to claim 4, wherein
the single crystal AlN substrate has a region in which the internal transmittance τ is 40% or more and 60% or less in a plan view.

6. The ultraviolet semiconductor light-emitting element according to claim 4, wherein
the region is along an outer edge on an upper surface of the single crystal AlN substrate.

7. An ultraviolet semiconductor light-emitting element comprising:
a single crystal AlN substrate;
an n-type AlGaN layer formed on the single crystal AlN substrate;
an active layer formed on the n-type AlGaN layer, the active layer having a light emission peak wavelength of 250 nm or more and 280 nm or less; and
a p-type AlGaN layer formed on the active layer, wherein
a light emission peak in a wavelength range of 450 nm or more and 800 nm or less is in a range of 590 nm or more and 610 nm or less in a light emission spectrum.

8. The ultraviolet semiconductor light-emitting element according to claim 7, wherein
an output of light with a wavelength of 590 nm or more and 610 nm or less during driving is 0.15 μW or more.

9. The ultraviolet semiconductor light-emitting element according to claim 7, wherein
the single crystal AlN substrate absorbs a part of an emitted light from the active layer and emits a light in a wavelength range of 590 nm or more and 610 nm or less due to the absorption of the emitted light.
